(19) United States
(12) Patent Application Publication
(10) Pub. No.: US 2009/0147115 A1
(43) Pub. Date: Jun. 11, 2009

(54) Solid-state image pick-up device, method for producing the same, and electronics device with the same

(75) Inventors: Yoshinori Tanida, Hiroshima (JP); Katsuitsu Nishida, Soraku-gun (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/313,864

(22) Filed: Nov. 25, 2008

(30) Foreign Application Priority Data
Nov. 26, 2007 (JP) 2007-305125

(51) Int. Cl. H04N 5/335; H01L 21/50

(52) U.S. Cl. 348/294; 438/64; 257/E21.499

(57) ABSTRACT

In accordance with the present invention of the solid-state image pickup device 100, a holder 31 is mounted along outer edge portion of the board 1 in such a manner that the holder 31 is mounted on a board 1 and on chip components 7 that are arranged on the outer edge portion of the board 1. The downsized solid-state image pickup device 100 can be attained hereby.

This Nonprovisional application claims priority under 35 U.S.C. § 119(a) on Patent Application No. 2007-305125 filed in Japan on Nov. 26, 2007, the entire contents of which are hereby incorporated by reference.

### FIELD OF THE INVENTION

The present invention relates to a downsized solid-state image pickup device, method for producing the same, and an electronics device with the same.

### BACKGROUND OF THE INVENTION

A solid-state image pickup device for capturing an image is provided with a solid-state image sensor (CCD (charge-coupled device) or CMOS (complementary metal-oxide semiconductor) sensor IC (integrated circuits)). The solid-state image pickup device is used for various types of portable devices as represented by communication devices such as mobile phones. Recently, portable devices are becoming smaller and slimmer, and therefore there is an increasing demand for smaller and slimmer solid-state image pickup devices.

Japanese Unexamined Patent Application Publication No. 2003-101000 (Patent Document 1) discloses a solid-state image pickup device aiming for downsizing. FIG. 4 is a cross-sectional view of the solid-state image pickup device in the patent document. As shown in FIG. 4, a board (basal plate) 201 of a solid-state image pickup device 200 is provided with a solid-state image sensor (sensor chip) 202 and peripheral devices 207. Further, in order to prevent dust entry into the solid-state image sensor 202, a lens holder 203 is fixed on the outer edge part of the board 201 by adhesive resin 206. The lens holder 203 comprises a holder 231, a lens 232, and a lens holder 233. The board 201 and the solid-state image sensor 202 are connected electrically via a wire 205. A transparent cover 204 is mounted in the holder 231 in such a way that the transparent cover 204 faces the solid-state image sensor 202.

However, the solid-state image pickup device in the patent document 1 has a problem in that the device cannot adapt to further downsizing demand.

More specifically, in accordance with the conventional solid-state image pickup device 200, all the peripheral devices 207 are contained inside the holder 231 as shown in FIG. 4. Therefore, the board 201 is designed to have such a size that is slightly extended beyond an arrangement area where the peripheral devices 207 are provided. That is, the board 201 cannot be downsized further than the arrangement area of peripheral devices 207. Therefore, the conventional solid-state image pickup device has a limitation for adapting to the further downsizing demand.

In order to downsize the solid-state image pickup device, it may be possible that, for instance, downsizing a chip of the solid-state image sensor 202, shortening a length of wire bonding, shortening a distance between the board 201 and the peripheral devices 207, and narrowing a width (wall thickness) of the holder 231.

However, the devices have been downsized already up to the limit in reality. Therefore, the downsizing of those devices cannot be performed anymore. Even if those are downsized, the effect of the downsizing is extremely small.

For instance, in order to shorten a space between the peripheral devices 207 from 0.25 mm to 0.23 mm, a highly sophisticated mounting technology will be required, only for obtaining the space reduction of merely 0.02 mm, and it cannot be the fundamental solution for downsizing.

### SUMMARY OF THE INVENTION

The present invention is accomplished in consideration of the above problems. An object of the invention is to provide a downsized solid-state image pickup device and a method for producing the same.

In order to attain the object, a solid-state image pickup device according to the present invention comprises: a board; a solid-state image sensor mounted on the board; one or more peripheral circuit sections provided in surroundings of the solid-state image sensor; and a holder mounted on the board, the holder containing the solid-state image sensor therein, wherein: at least one of the peripheral circuit sections is an outer edge circuit section located on an outer edge part of the board; and the holder is mounted on the board and on the outer edge circuit section along the outer edge part of the board.

A conventional solid-state image pickup device is configured such that a solid-state image sensor and all peripheral circuit sections are contained in a holder. That is, the holder is mounted only on the board. Therefore, the board is sized beyond the area in which the outermost peripheral circuit sections are arranged.

On the other hand, in accordance with the present solid-state image pickup device, the solid-state image sensor is contained in the holder as well. However, the peripheral circuit sections (outer edge circuit sections) arranged on the outer edge part of the board are not contained in the holder. That is, not all the peripheral circuit sections are contained in the holder. Moreover, the holder is mounted along the outer edge part of the board. That is, the holder is mounted not only on the board, but also on the outer edge circuit section. For this reason, the size of the board is the same as the size just enough to contain the outermost area in which the outer edge circuit sections are arranged. Therefore, the downsizing further than the conventional solid-state image pickup device becomes possible.

On the condition that at least one outer edge circuit section is arranged on the outer edge part of the board, the solid-state image pickup device is downsized further than the conventional device.

In order to attain the object, a method according to the present invention for producing a solid-state image pickup device is a method for producing a solid-state image pickup device which includes a board; a solid-state image sensor mounted on the board; one or more peripheral circuit sections provided in surroundings of the solid-state image sensor; and a holder mounted on the board, the holder containing the solid-state image sensor therein, wherein: at least one of the peripheral circuit sections is an outer edge circuit section located on an outer edge part of the board; and the method comprise mounting the holder on the board and on the outer edge circuit section along the outer edge part of the board.

In accordance with the method, not all the peripheral circuit sections (outer edge circuit sections) are contained inside the holder. Moreover, the holder is mounted along the outer edge part of the board. That is, the holder is mounted not only on the board, but also on the outer edge circuit section. For this reason, the size of the board can be the same as the size of outermost area in which the outer edge circuit sections are arranged. Therefore, it is possible to make the downsized solid-state image pickup device further than the conventional device.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross-sectional view of a schematic configuration of a solid-state image pickup device of the present invention.

FIG. 2 is an exploded view of the solid-state image pickup device shown in FIG. 1 without the lens unit.

FIG. 3 is a side view of the solid-state image pickup device shown in FIG. 1.

FIG. 4 is a cross-sectional view of the solid-state image pickup device in Patent Document 1.

FIG. 5 is an exploded view of the solid-state image pickup device shown in FIG. 4.

FIG. 6 is a side view of the solid-state image pickup device shown in FIG. 4.

### DESCRIPTION OF THE EMBODIMENTS

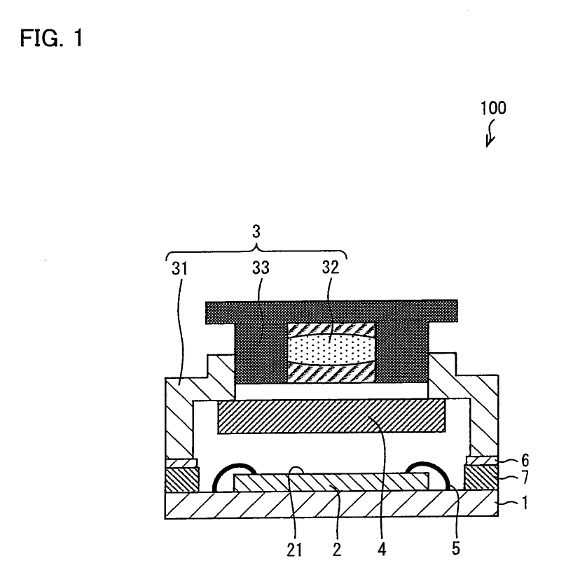

One embodiments of the present invention is described below in reference to the drawings. FIG. 1 is a cross-sectional view of a schematic configuration of a solid-state image pickup device according to the present invention.

A solid-state image pickup device 100 includes a solid-state image sensor 2, a lens unit 3, and a chip component 7 on a board 1. Further, the lens unit 3 includes a transparent cover 4 facing the solid-state image sensor 2. The board 1 and the solid-state image sensor 2 are connected via a wire 5 with wire bonding.

The board 1 draws out signals from the solid-state image sensor 2 and has a patterned wiring not shown in the drawings. That is, the board 1 and the solid-state image sensor 2 are connected electrically via the wiring. The board 1 is, for instance, a printed circuit board, a ceramic substrate, and so on. On the backside of the board 1, an electrode (not illustrated) is provided for external connection.

The solid-state image sensor 2 is arranged in a center of the board 1, and that is a semiconductor substrate (for instance, a silicon monocrystalline substrate), which has a two-dimensionally rectangular shape and on which a semiconductor circuit is provided. The solid-state image sensor 2 is, for instance, a CCD (charge-coupled device) image sensor, a CMOS (complementary metal-oxide semiconductor) image sensor, or a VMIS (threshold voltage modulation image sensor). The solid-state image sensor 2 comprises an effective pixel area (imaging area) 21 in which a plurality of light receiving elements (pixels) is arranged in matrix. The effective pixel area 21 is a light receiving section (light receiving surface) of the solid-state image sensor 2. The effective pixel area 21 is located in a center of the principal surface (front face) of the solid-state image sensor 2 and has a rectangular shape two-dimensionally. Further, the light receiving element converts the subject image (transmitted light through the transparent cover 4) formed on the effective pixel area 21 into an electric signal. The board 1 in the solid-state image pickup device 100 in the present embodiment has a thickness thicker than that of the solid-state image sensor 2. The solid-state image sensor 2 is stuck with the board 1 by adhesive (not illustrated).

The lens unit 3 leads light from outside to the solid-state image sensor 2. That is, the lens unit 3 forms an image on the solid-state image sensor 2 from external information. The lens unit 3 comprises a holder 31 mounted on the board 1, and a lens holder 33 (a tube, a light path defining device) held in an opening in a center of an upper portion of the holder 31. The lens 32 is held inside the lens holder 33.

The holder 31 is hollow and the transparent cover 4 is provided inside the holder 31 in such a manner that the transparent cover 4 faces the solid-state image sensor 2. The detail of the holder 31 is described later. The transparent cover 4 is stuck with the holder 31 by adhesive (not illustrated).

The transparent cover 4 is mounted to cover the effective pixel area 21 of the solid-state image sensor 2. The transparent cover 4 comprises a transparent material such as glass or resin. As described later, the holder 31 is stuck with the board 1 and the chip components 7 by the adhesive resin 6. The transparent cover 4 may comprise an optical filter such as an infrared cut filter that cuts entering infrared rays on the solid-state image sensor 2.

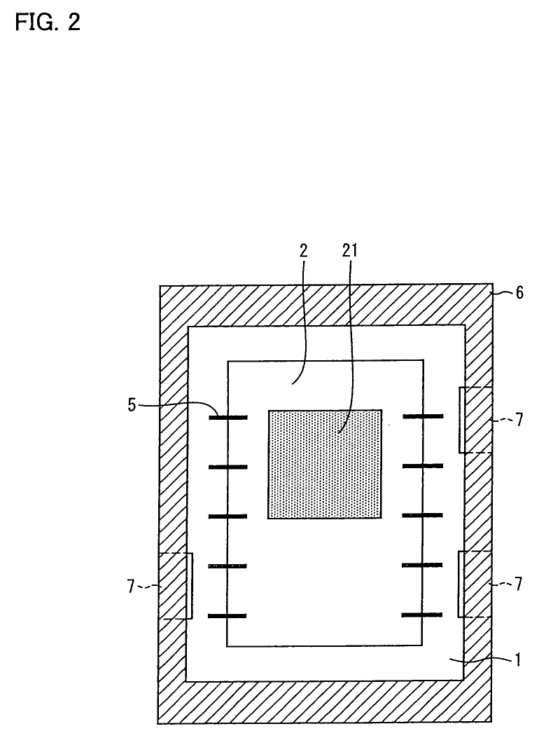

FIG. 2 is an exploded view of the solid-state image pickup device 100 shown in FIG. 1 without the lens unit 3. As shown in FIG. 2, a plurality of the chip components 7 (peripheral circuit sections, outer edge circuit sections) is mounted around the solid-state image sensor 2 on the board 1. In FIG. 2, only the chip components 7 (outer edge circuits) on an outer edge part of the board 1 are shown. However, the chip components 7 may be mounted on the other part of the board 1 than the outer edge part. In this case, a stack structure (the part of the chip components 7 is stacked on the solid-state image sensor 2) is possible.

The chip components 7 are electronic components necessary for driving the solid-state image pickup device 100, such as a signal processing circuit for the solid-state image sensor 2. More specifically, the signal processing circuit controls the operation of the solid-state image sensor 2, and performs as a control part (image processor) providing necessary signals by processing the outputted signals from the solid-state image sensor 2 accordingly. For instance, the signal processing circuit is provided with electronic components such as an amplifying circuit section (analog signal circuit section) that amplifies the electric signal converted from the light by the light receiving element of the effective pixel area 21 and outputs the electric signal as an analog signal, an analog/digital conversion processing circuit section that converts the analog signal into a digital signal, a DSP (digital signal processor) that controls the operation of the solid-state image sensor 2, a CPU that performs a various kinds of arithmetic processing according to programs, a ROM that stores the programs, and a RAM that stores such data of each process stage. The electronic components also encompass a resistor and a capacitor.

The adhesive resin 6 is applied on the outer edge part of the board 1. The adhesive resin 6 is applied not only on the board 1, but also on the chip components 7 of the outer edge part of the board 1. The adhesive resin 6 sticks the board 1 with the holder 31 in the area that the chip components 7 do not exist (the board 1 is exposed). On the other hand, in the area that the chip components 7 exist, the adhesive resin 6 sticks the chip components 7 with the holder 31. The adhesive resin 6 can comprise adhesive thermosetting resin and light (for instance, ultraviolet) cure resin. Moreover, the adhesive resin 6 can also be applied on the board 1 (inside the holder 31) as long as the resin 6 does not reach the effective pixel area 21 of the solid-state image sensor 2.

In the solid-state image pickup device 100 having the above configuration, the external light is taken in via the lens unit 3, and then the light thus taken in is guided into inside through the transparent cover 4. The light receiving elements disposed in the effective pixel area 21 of the solid-state image sensor 2 receives the light as an image. In accordance with the solid-state image pickup device 100, the space between the effective pixel area 21 and the transparent cover 4 is hollow. Therefore, the external light passed through the transparent cover 4 reaches directly the effective pixel area 21 without causing light loss along the light path.

One most significant feature of the solid-state image pickup device 100 is such that the holder 31 is mounted along the outer edge part of the board 1 in such a manner that the holder 31 is mounted on the board 1 and on the chip components 7 arranged on the outer edge part, thereby downsizing further than the conventional solid-state image pickup device.

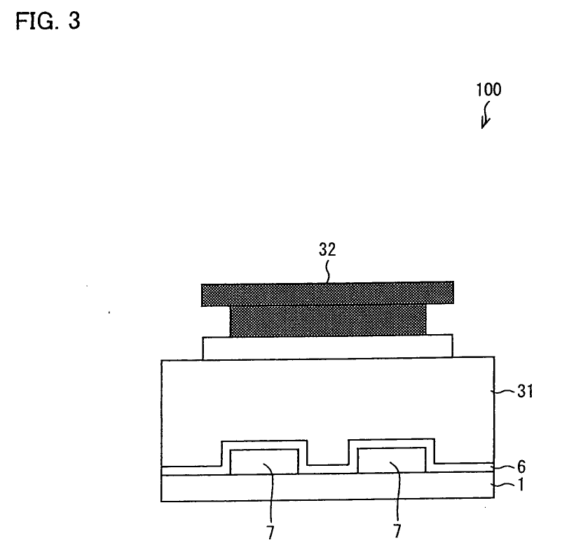

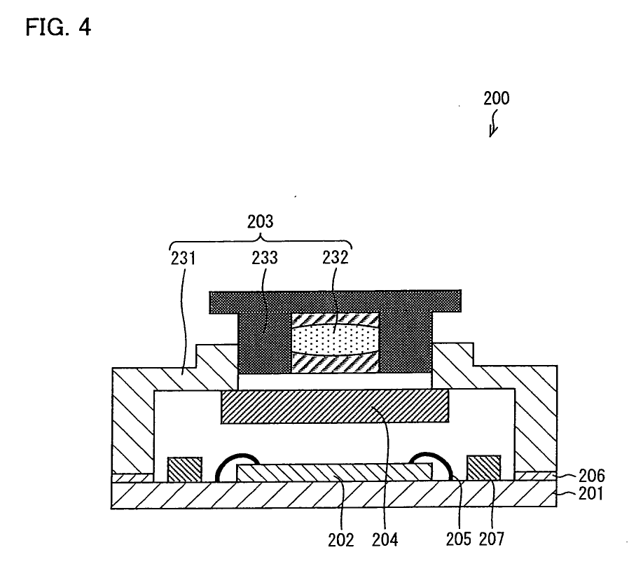

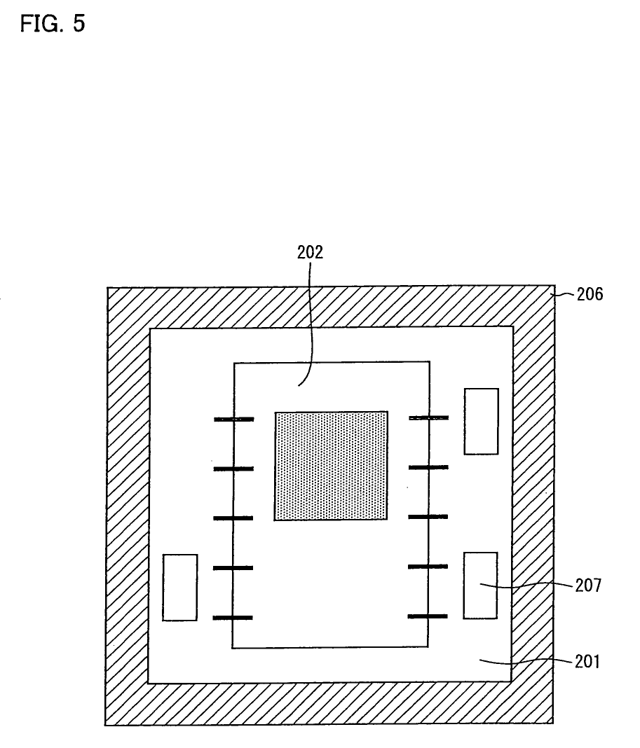

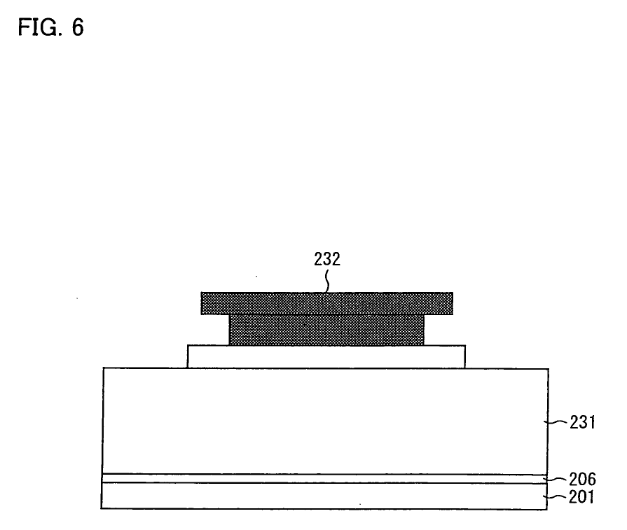

This significant feature is described below in reference to FIGS. 1 to 3 illustrating the solid-state image pickup device 100. FIG. 3 is a side view of the solid-state image pickup device shown in FIG. 1. The following description also refers to FIGS. 4 to 6 illustrating the conventional solid-state image pickup device. FIG. 4 is a cross-sectional view of a conventional solid-state image pickup device, FIG. 5 is an exploded view (partial top view) of the solid-state image pickup device shown in FIG. 4, and FIG. 6 is a side view of the solid-state image pickup device shown in FIG. 4. Each of FIGS. 4 to 6 corresponds to FIGS. 1 to 3.

As shown in FIGS. 4 and 5, a conventional solid-state image pickup device 200 is configured such that a solid-state image sensor 202 and all the peripheral components 207 are contained in a holder 231. For this reason, the holder 231 is mounted only on a board 201. Therefore, the board 201 is sized beyond the outermost area in which the peripheral components 207 are arranged on the board 201.

On the other hand, as shown in FIGS. 1 and 2, the solid-state image pickup device 100 of the present embodiment is also configured such that the solid-state image sensor 2 is contained in the holder 31. However, the chip components 7 arranged on the outer edge part of the board 1 are not contained in the holder 31, in solid-state image pickup device 100. That is, not all the chip components 7 are contained inside the holder 31. Moreover, the holder 31 is mounted along the outer edge part of the board 1. That is, the holder 31 is mounted not only on the board 1, but also on one/ones of the chip components 7 which is/are located on the outer edge part. For this reason, the size of the board 1 is the same as the size just enough to contain the outermost area in which the chip components 7 are arranged. Therefore, the downsizing further than the conventional solid-state image pickup device 200 is possible.

On the condition that at least one of the chip components 7 is mounted on the outer edge part of board 1, the solid-state image pickup device is downsized further than the conventional solid-state image pickup device.

Moreover, the conventional solid-state image pickup device 200 is configured such that all of the peripheral components 207 are contained in the holder 231. Therefore, as shown in FIG. 5, the adhesive resin 206 applied on the outer edge part of the board 201 is applied on the outer side with respect to the peripheral components 207. That is, the adhesive resin 206 is applied only on the board 201. For this reason, the adhesive resin 206 is applied in the flat. Therefore, the bottom face of the holder 231 is also flat as shown in FIG. 6.

On the other hand, in accordance with the present embodiment of the solid-state image pickup device 100, the chip components 7 mounted on the outer edge part of the board 1 is not contained inside the holder 31. Therefore, as shown in FIG. 2, the adhesive resin 6 is applied not only on the board 1, but also on the chip components 7. That is, the board 1 has an exposed area (flat part) and an area on which the chip components 7 are mounted (mountain part). For this reason, the adhesive resin 6 has an up-and-down shape along the flat and mountain portion on the board 1. Therefore, as shown in FIG. 3, the bottom face of the holder 31 has an up-and-down shape.

As described above, in accordance with the present embodiment of the solid-state image pickup device 100, the shapes of the adhesive resin 6 and the bottom face of the holder 31 are different from those of the conventional solid-state image pickup device 200.

Moreover, in accordance with the present embodiment of the solid-state image pickup device 100, the downsizing is possible as far as one or more chip components 7 are mounted on the outer edge part of the board 1. Further, in case a plurality of the chip components 7 is mounted, the arrangement pattern of those components is not limited. However, it is preferable that a plurality of the chip components 7 is mounted on the outer edge part of the board 1, and the chip components 7 are arranged in asymmetrically as shown in FIG. 2.

When a plurality of the chip components 7 is arranged asymmetrically on the outer edge part of the board 1, surface shape (up-and-down surface shape) of the board 1 and the bottom face shape (up-and-down shape) of the holder 31 are also asymmetrical. Because of the asymmetrical arrangement, the holder 31 is mounted on the board 1 only when the board 1 and the holder 31 are specifically aligned. By doing so, the holder 31 cannot be mounted on the board 1 in a wrong arrangement condition. Therefore, the alignment (layout) of the board 1 and the holder 31 in manufacturing is easily performed, and thereby the manufacturing efficiency is improved.

In semiconductor equipments other than a solid-state image pickup device, the alignment of a board and components to be mounted on the board may be performed by using latch structures provided to the board and the mounted components, respectively, so that the board and the components to be mounted thereon are latched with each other. However, the solid-state image pickup device 100 has almost no extra space because the chip components 7 are mounted so densely on the board 1. That is, there is no space for providing such alignment (latching) structure. For this reason, such kind of alignment structure cannot be applied for the board and the holder.

Moreover, in the present embodiment of the solid-state image pickup device 100, as shown in FIG. 1 and FIG. 3, it is preferable that whole backsides of the chip components 7 mounted on the outer edge part of the board 1 contact the board 1. With this configuration, there is no gap between the board 1 and the chip components 7 because whole backsides of the chip components 7 contact the board 1. This prevents a leakage of light into the effective pixel area 21 of the solid-state image sensor 2. That is, entering light on the solid-state image sensor 2 can be shutoff. Further, entries of dust or foreign bodies into the holder 31 (into the solid-state image pickup device 100) can be prevented.

Moreover, in the present embodiment of the solid-state image pickup device 100, the adhesive resin 6 may be omitted. In case the adhesive resin 6 is applied, it is preferable that the adhesive resin 6 is applied so that the gap between the board 1 and the holder 31, and the gap between the chip components 7 and the holder 31 are filled with the adhesive resin 6 as shown in FIG. 3. In this configuration, the adhesive resin 6 is filled between the board 1 and the holder 31, and between the chip components 7 and the holder 31, and each gap is closed up (sealed) with the adhesive resin 6. With this configuration, the light is prevented from entering into the effective pixel area 21 of the solid-state image sensor 2 through each gap. That is, entering light into the solid-state image sensor 2 through each gap can be shutoff. Moreover, entries of dust or foreign bodies into the holder 31 (into the solid-state image pickup device 100) can be prevented.

Moreover, the downsizing of the solid-state image pickup device 100 can be achieved regardless of whether the adhesive resin 6 may be made of transparent resin or opaque resin. If the adhesive resin 6 is made of opaque resin such as colored resin, the adhesive resin 6 has a light-shielding characteristic. This prevents the leakage of light into the effective pixel area 21 of the solid-state image sensor 2. Therefore, it is preferable that the adhesive resin 6 is made of a light-shielding material.

In accordance with the method for producing the solid-state image pickup device 100, for instance, the solid-state image sensor 2 and the chip components 7 are mounted on the board 1. Then, the adhesive resin 6 is applied on the board 1, and the holder 31 is mounted thereon. The solid-state image pickup device 100 can be made hereby.

More specifically, first, the solid-state image sensor 2 and the chip components 7 are mounted on the board 1. Then, the holder 31 is formed according to the shape of the outer edge part of the board 1. The holder 31 is formed to have a shape corresponding to the up-and-down shape of the surface of the board 1. For instance, the holder 31 is formed by metal molding.

Then, the adhesive resin 6 is applied on the outer edge part of the board 1. The adhesive resin 6 is applied not only on the board 1, but also on the chip components 7 mounted on the board 1.

Finally, the adhesive resin 6 is cured. In this way, the solid-state image pickup device 100 is made. The solid-state image pickup device 100 downsized further than the conventional solid-state image pickup device can be made hereby.

In the method for producing the solid-state image pickup device 100, the adhesive resin 6 may be applied as a sheet on the outer edge part of the board 1, and then, the applied adhesive resin 6 is melted, and cured thereafter. When the adhesive resin 6 applied as a sheet on the outer edge part of the board 1 is melted, the melted adhesive resin 6 flows into the gaps between the board 1 and the holder 31, and between chip components 7 and the holder 31. Therefore, each gap is closed up (sealed) with the adhesive resin 6. This prevents the leakage of light into the light receiving part of the solid-state image sensor 2 through each gap. That is, entering light into the solid-state image sensor 2 through each gap can be shutoff. Moreover, the entries of dust or foreign bodies through each gap into the holder (into the solid-state image pickup device 100) can be prevented.

The present solid-state image pickup device is suitable for use in electronics devices with photograph function such as a camera-equipped mobile phone, a digital still camera, a camcorder, and a security camera.

As is described above, the present solid-state image pickup device is configured such that the holder is mounted on the board and on the outer edge circuit section along the outer edge part of the board. For this reason, the size of the board is the same as the size just enough to contain outermost area in which the outer edge circuit sections are arranged. Therefore, the downsizing further than the conventional solid-state image pickup device becomes possible.

In the present solid-state image pickup device, it is preferable that the outer edge circuit sections are provided more than one and arranged asymmetrically.

In accordance with the above configuration, the peripheral circuit sections on the outer edge part of the board (a plurality of the outer edge circuits) are arranged asymmetrically. Therefore, the surface shape of the board and the bottom face of the holder are also asymmetrical. The holder can be mounted on the board only when the board and the holder are in the specific arrangement condition. For that reason, the holder cannot be mounted on the board in a wrong arrangement condition. Therefore, the alignment (layout) of the board and the holder in manufacturing is easily performed, and thereby the manufacturing efficiency is improved.

In semiconductor equipments other than a solid-state image pickup device, the alignment of the board and the mounted components can be performed by the latch structure between the board and the mounted components. However, in the solid-state image pickup device, there is almost no extra space because the peripheral circuit sections are mounted densely on the board. That is, there is no space for providing an alignment (latching) structure. For this reason, such kind of alignment structure cannot be applied for the board and the holder.

In the present solid-state image pickup device, it is preferable that the outer edge circuit section has a backside that is wholly in contact with the board.

In the above configuration, there is no gap between the board and the outer edge circuit sections because whole backsides of the outer edge circuit sections contact the board. This prevents the leakage of light into the light receiving part of the solid-state image sensor. That is, entering light into the solid-state image sensor can be shutoff. Moreover, entries of dust or foreign bodies into the holder (into the solid-state image pickup device) can be prevented.

The present solid-state image pickup device preferably further comprises adhesive resin applied so that the gap between the board and the holder, and the gap between the outer edge circuit sections and the holder are filled with the adhesive resin.

In the above configuration, the adhesive resin is filled between the board and the holder, and between the outer edge circuit sections and the holder, and each gap is closed up (sealed) with the adhesive resin. This prevents a leakage of light into the light receiving part of the solid-state image sensor through each gap. That is, entering light into the solid-state image sensor through each gap can be shutoff. Moreover, entries of dust or foreign bodies into the holder (into the solid-state image pickup device) can be prevented.

In the present solid-state image pickup device, it is preferable that the adhesive resin is made of a light-shielding material.

In the above configuration, the adhesive resin has a light-shielding characteristic. This prevents the leakage of light into the light receiving part of the solid-state image sensor. That is, entering light through the adhesive resin on the solid-state image sensor can be shutoff.

Moreover, a method according to the present invention for producing a solid-state image pickup device is a method for producing a solid-state image pickup device which includes a board; a solid-state image sensor mounted on the board; one or more peripheral circuit sections provided in surroundings of the solid-state image sensor; and a holder mounted on the board, the holder containing the solid-state image sensor therein, wherein: at least one of the peripheral circuit sections is an outer edge circuit section located on an outer edge part of the board; and the method comprise mounting the holder on the board and on the outer edge circuit section along the outer edge part of the board.

In accordance with the method, the peripheral circuit sections (outer edge circuit sections) arranged on the outer edge part of the board are not contained in the holder. Moreover, the holder is mounted along the outer edge part of the board. That is, the holder is mounted not only on the board, but also on the outer edge circuit section. For this reason, the size of the board is the same as the size of the outermost area in which the outer edge circuit sections are arranged. Therefore, it is possible to make the downsized solid-state image pickup device further than the conventional device.

In the method for producing the solid-state image pickup device preferably comprises: applying adhesive resin of a sheet form onto the outer edge part of the board; melting the applied adhesive resin; and curing the melted resin.

In accordance with the method, when the adhesive resin applied as a sheet on the outer edge part of the board is melted, the melted adhesive resin flows into the gaps between the board and the holder, and between the outer edge circuit sections and the holder. Therefore, each gap is closed up (sealed) with the adhesive resin. This prevents the leakage of light into the light receiving part of the solid-state image sensor through each gap. That is, entering light into the solid-state image sensor through each gap can be shutoff. Moreover, entries of dust or foreign bodies through each gap into the holder (into the solid-state image pickup device) can be prevented.

The present invention can produce an extremely downsized solid-state image pickup device (camera module). Therefore, the present invention is suitable for use in various types of portable devices as represented by communication devices and portable phones those are requested to be smaller and slimmer.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A solid-state image pickup device comprising:
a board;
a solid-state image sensor mounted on the board;
one or more peripheral circuit sections provided in surroundings of the solid-state image sensor; and
a holder mounted on the board, the holder containing the solid-state image sensor therein,
wherein:
at least one of the peripheral circuit sections is an outer edge circuit section located on an outer edge part of the board; and
the holder is mounted on the board and on the outer edge circuit section along the outer edge part of the board.

2. The solid-state image pickup device according to claim 1, wherein the outer edge circuit sections are provided more than one and arranged asymmetrically.

3. The solid-state image pickup device according to claim 1, wherein the outer edge circuit section has a backside that is wholly in contact with the board.

4. The solid-state image pickup device according to claim 1, further comprising adhesive resin applied so that a gap between the board and the holder, and a gap between the outer edge circuit section and the holder are filled with the adhesive resin.

5. The solid-state image pickup device according to claim 4, wherein the adhesive resin is made of a light-shielding material.

6. A method for producing a solid-state image pickup device which includes a board; a solid-state image sensor mounted on the board; one or more peripheral circuit sections provided in surroundings of the solid-state image sensor; and a holder mounted on the board, the holder containing the solid-state image sensor therein,
wherein:
at least one of the peripheral circuit sections is an outer edge circuit section located on an outer edge part of the board; and
the method comprises mounting the holder on the board and on the outer edge circuit section along the outer edge part of the board.

7. The method according to claim 6, further comprising:
applying adhesive resin of a sheet form onto the outer edge part of the board;
melting the applied adhesive resin; and curing the melted resin.

8. An electronics device comprising:
a solid-state image pickup device,
the solid-state image pickup device including:
a board;
a solid-state image sensor mounted on the board;
one or more peripheral circuit sections provided in surroundings of the solid-state image sensor; and
a holder mounted on the board, the holder containing the solid-state image sensor therein,
wherein:
at least one of the peripheral circuit sections is an outer edge circuit section located on an outer edge part of the board; and
the holder is mounted on the board and on the outer edge circuit section along the outer edge part of the board.
